(19) United States
(12) Patent Application Publication
(10) Pub. No.: US 2009/0015235 A1
(43) Pub. Date: Jan. 15, 2009

(54) METHOD AND APPARATUS FOR TESTING A SYSTEM MODULE

(75) Inventors: Wen-Jiunn Tsay, Taipei Hsien (TW); David Yow-Chern Chang, Taipei Hsien (TW); Bao-Tai Hwang, Taipei Hsien (TW); Ling-Haur Huang, Taipei Hsien (TW)

Correspondence Address: KNOBBE MARTENS OLSON & BEAR LLP, 2040 MAIN STREET, FOURTEENTH FLOOR, IRVINE, CA, 92614, US

(73) Assignee: AirDio Wireless Inc., Taipei Hsien (TW)

(21) Appl. No.: 11/775,115

(22) Filed: Jul. 9, 2007

(51) Int. Cl. G01R 31/28

(52) U.S. Cl. 324/73.1

(57) ABSTRACT

A method for testing a system module assembled by integrated circuits during mass production. The integrated circuits and the assembled system modules are manufactured by the same manufacturer. The method includes the steps of apply a plurality of system level tests to the system module to determine the performance of the system module. Next, verify the performance of the integrated circuits based on the results of the system level tests. Finally, perform integrated circuit level tests, wherein the integrated circuit level tests include test items unverifiable by the system level tests. The present invention also includes a testing apparatus for testing a system module.

### BACKGROUND

1. Field of Invention

The present invention relates to a method and apparatus for testing a system module. More particularly, the present invention relates to a method and apparatus for testing a system module during mass production.

2. Description of Related Art

Nowadays, the system module manufacturers such as manufacturers of various portable electronics devices assemble the system modules by using integrated circuits fully tested at the integrated circuit level during mass production. Please refer to FIG. 1, a flow diagram of the current manufacturing procedure from chip design to assembled systems as the end product. The integrated circuits used are provided by integrated circuits manufacturer A different from the system module manufacturer B. Manufacturer A designs the integrated circuits in the design phase 102 and enters the mass production phase 104 upon completion of the chip design. During and after the mass production phase, the integrated circuits are testing extensively with expensive testing equipments such as RF probe station and RF ATE (Automatic Test Equipment). After the testing and characterization of the manufactured chips, they are packaged and sent to manufacturer B for assembling into system modules. During the mass production phase 106 of the system modules, the system level performance is tested to ensure the compatibility of the integrated circuits with the assembled system module.

The foregoing is the standard testing procedure relating to the integrated circuits manufacturer and the system modules manufacturer. Testing the chips at the integrated circuit level requires pieces of expensive testing equipment in order to fully characterize the specifications of the chips. However, from a practical point of view, even if a chip is fully characterized, it will still have to meet the requirement of the application for the chip to fulfill its intended purpose. Therefore, often the concern of the system module manufacturers B is in the performance of the chip when it is operated within the system module and not individual performance of the chip at the integrated circuit level. Nevertheless, the integrated circuits manufacturers will still fully test the chips at the integrated circuit level because to the integrated circuits manufacturers A, the chips are the end product, and thus need to be fully characterized.

If the integrated circuits and the system modules are manufactured by the same manufacturer, the end product becomes the system module, and thus the standard testing procedure during mass production need not remain the same.

For the forgoing reasons, there is a need for a new method and a new testing apparatus for testing a system module assembled by integrated circuits during mass production, wherein the integrated circuits and the assembled system modules are manufactured by the same manufacturer.

### SUMMARY

The present invention is directed to a method and an apparatus for testing a system module assembled by integrated circuits during mass production, that is satisfies this need of a new method of testing the system module when the integrated circuits and the assembled system modules are manufactured by the same manufacturer. The method comprises applying system level tests to the system module to determine the performance of the system module. Next, verify the performance of the integrated circuits based on the results of the system level tests. Perform integrated circuit level tests, wherein the integrated circuit level tests include test items unverifiable by the system level tests.

The method of the present invention eliminates the need for substantial integrated circuit level tests (parametric tests), due to the fact that the test items in the system level tests has correlation with the test items in parametric tests. Thus, if the test results in system level tests comply with the system specifications, then since the system specifications and parametric specifications are correlated, the performance of the chips at integrated circuit level may be considered to comply with industry standards. In other words, the system tests covers most of the parametric tests, and the system test items may be grouped with the parametric test items based on their correlation.

Some integrated circuit level test items may not be verifiable at the system level, and therefore will need additional measures to verify such items separately. However, the unverifiable test items can be tested by inexpensive testing equipments thus does not increase the overall cost of the test equipments significantly.

The embodiment of the present invention further includes a testing apparatus for testing the system modules, wherein the testing apparatus includes a system level testing sector and an integrated circuit level testing sector. The system level testing sector is for performing system level tests on the system module to determine the performance of the system module and the integrated circuits. The integrated circuit level testing sector is for performing integrated circuit level tests comprising test items unverifiable by the system level tests.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a flow diagram of the current manufacturing procedure from chip design to assembled systems as the end product; and

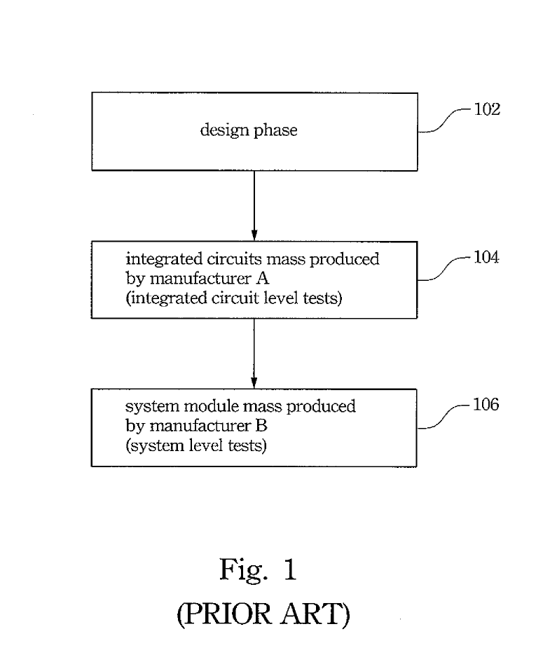

FIG. 2 is a flow diagram of the method for testing the system modules according to an embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

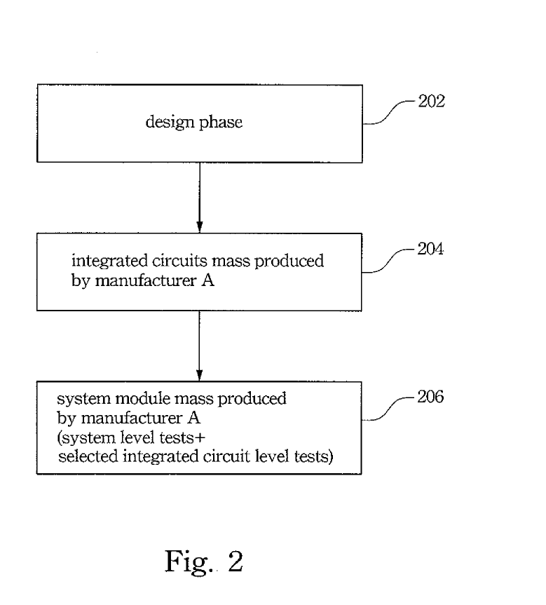

Please refer to FIG. 2, a flow diagram of the method for testing the system modules according to an embodiment of the present invention. In this embodiment, the end product is a mobile handset. The manufacturer A manufactures the integrated circuits used by the mobile handset and also the handset itself. The integrated circuits may include RF transceiver chips, baseband/MAC chips, power amplifiers, RF and IF filters, crystal oscillators, duplexers . . . etc.

Since the end product is the mobile handset, the integrated circuits may be designed to meet the specifications of the mobile handset. In this example, the integrated circuits are designed in the design phase 202, and mass produced at the mass production phase 204. They are packaged and assembled into system modules at the mass production phase 206 without undergoing integrated circuit level tests. In the mass production phase 206, the handsets are tested at the system level.

The integrated circuit level tests may be omitted because if the end product is the handset, then the ultimate standard for compliance is the system level tests, which indicates the performance of the handset. The integrated circuit level tests verify the performance of individual chips, which is not the ultimate concern for manufacturer A. The embodiment of the present invention does not intend to dismiss the importance of individual chips meeting parametric specifications, rather, provided that most integrated circuit level tests items are correlated with system level test items, the system level tests may cover the integrated circuit level tests.

For example, system test items of a mobile handset may include RF transmitter output power, RF receiver sensitivity, signal frequency error, signal phase error, spectrum due to modulation, and error vector magnitude (EVM) . . . etc. Taking EVM as an example, the EVM performance of a mobile handset is correlated with parametric test items such as I/Q imbalance, phase noise, spurious signals, signal compression (such as IP2, IP3 performances), and transient effects. From the correlation, manufacturer A may conclude that if the EVM of the handset complies with the system specifications, then the above mentioned parametric specifications also comply. If the EVM of the handset does not comply with the system specifications, then the source of the problem may be traced to the above mentioned parametric specifications.

By the same token, each integrated circuit level test item may be grouped with system level test items based on their correlation. Such correlation allows most of the parametric testing performed at the integrated circuit level to be omitted during mass production of the system module, in this example, the mobile handset. The omission of parametric tests reduce the cost of overall capital on testing equipments significantly, since integrated circuit level testing, such as RF probe station and RF ATE, uses the most expensive equipments. Also, the omission of parametric testing can accelerate and simplify the mass production procedures since the performance of the integrated circuits are implied in the system level tests.

In practice, some integrate circuit level test items may not be able to be verified at the system level. Such items may include direct current (DC) tests, and selected digital signal tests. These tests will require additional equipment for verification. However, the testing equipment used to perform such integrated circuit level testing is often inexpensive, and may be part of a system level testing equipment.

Therefore, the present invention also provides a testing apparatus for testing a system module assembled by integrated circuits in mass production. The testing apparatus includes a system level testing sector for performing system level tests on the system module to determine the performance of the system module and the integrated circuits. For example, the system level testing sector will perform tests such as RF transmitter output power, RF receiver sensitivity, signal frequency error, signal phase error, and error vector magnitude (EVM) as mentioned above on a mobile handset. The testing apparatus also includes an integrated circuit level testing sector to perform integrated circuit level tests comprising test items unverifiable by the system level tests. For example, DC tests and selected digital signal tests are performed on the chips by the integrated circuit level testing sector.

From a systems point of view, integrated circuit level tests are intermediate testing procedures taken to test an intermediate product. Therefore, if a manufacturer manufactures the chips as well as the system module, then the final product (i.e. mobile handset) undergoing final tests (system level tests) are sufficient enough to verify the performance of the final product.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for testing a system module assembled by a plurality of integrated circuits during mass production, wherein the integrated circuits and the assembled system modules are manufactured by the same manufacturer, comprising:
applying a plurality of system level tests to the system module to determine the performance of the system module;
verifying the performance of the integrated circuits based on the results of the system level tests; and
performing a plurality of integrated circuit level tests, wherein the integrated circuit level tests comprise test items unverifiable by the system level tests.

2. The method of claim 1, wherein the manufacturer manufactures the integrated circuits according to the specifications of the system modules.

3. The method of claim 1, wherein the integrated circuit level tests are parametric tests.

4. The method of claim 1, wherein the system level tests comprise radio communication system transmitter output power test, receiver sensitivity tests, frequency error tests, phase error tests, spectrum due to modulation tests, and error vector magnitude tests.

5. The method of claim 1, wherein the system module is a portable electronics device.

6. The method of claim 1, wherein the performance of integrated circuits is verified by grouping a plurality of integrated circuits level specifications with a plurality of correlating system level specifications, such that the performance of the system module indicates the performance of the integrated circuits based on the correlation.

7. The method of claim 1, wherein the test items are direct current measurements at the integrated circuit level.

8. The method of claim 1, wherein the test items are digital signal verifications at the integrated circuit level.

9. A testing apparatus for testing a system module assembled by a plurality of integrated circuits in mass production, wherein the integrated circuits and the assembled system module are manufactured by the same manufacturer, comprising:
a system level testing sector for performing system level tests on the system module to determine the performance of the system module and the integrated circuits; and
an integrated circuit level testing sector to perform integrated circuit level tests comprising test items unverifiable by the system level tests.

10. The apparatus of claim 9, wherein the manufacturer manufactures the integrated circuits according to the specifications of the system modules.

11. The apparatus of claim 9, wherein the integrated circuit tests are parametric tests.

12. The apparatus of claim 9, wherein the system level tests comprise radio communication system transmitter output power test, receiver sensitivity tests, frequency error tests, phase error tests, spectrum due to modulation tests, and error vector magnitude tests.

13. The apparatus of claim 9, wherein the system module is a portable electronics device.

14. The apparatus of claim 9, wherein the performance of integrated circuits is determined by grouping a plurality of integrated circuit level specifications with a plurality of correlating system level specifications, such that the performance of the system module indicates the performance of the integrated circuits based on the correlation.

15. The apparatus of claim 9, wherein the test items are direct current measurements at the integrated circuit level.

16. The apparatus of claim 9, wherein the test items are digital signal verifications at the integrated circuit level.
